(19) United States
(12) Patent Application Publication
(10) Pub. No.: US 2019/0160912 A1
(43) Pub. Date: May 30, 2019

(54) CONTROL APPARATUS AND CONTROL METHOD FOR VEHICLE

(71) Applicant: TOYOTA JIDOSHA KABUSHIKI KAISHA, Toyota-shi (JP)

(72) Inventor: Takashi AMANO, Susono-shi (JP)

(73) Assignee: TOYOTA JIDOSHA KABUSHIKI KAISHA, Toyota-shi (JP)

(21) Appl. No.: 16/193,265

(22) Filed: Nov. 16, 2018

(30) Foreign Application Priority Data
Nov. 27, 2017 (JP) 2017-226639

(51) Int. Cl. B60H 1/00; H01M 6/50

(52) U.S. Cl. CPC B60H 1/00742; B60H 1/00028; H05K 7/20; B60H 1/00878; H01M 6/5038; B60H 1/00792

(57) ABSTRACT

In a control apparatus for a vehicle and a control method for the vehicle, when a heating operation is executed, an ECU controls an operating point of an engine to a target operating point that is defined as the same operating point of the engine as at the time of normal operation when heating operation is not performed, when the engine operates in a high-load region. Moreover, when the heating operation is executed, the ECU controls the operating point of the engine to a target operating point that is defined as an operating point of the engine at which an output of the engine is larger than at the time of normal operation, when the engine operates in a low-load region or an intermediate-load region.

### CROSS-REFERENCE TO RELATED APPLICATIONS

This application claims priority to Japanese Patent Application No. 2017-226639 filed on Nov. 27, 2017, which is incorporated herein by reference in its entirety.

### BACKGROUND

### 1. Technical Field

The disclosure relates to a control apparatus for a vehicle and a control method for the vehicle.

### 2. Description of Related Art

In Japanese Patent Application Publication No. 2015-166204 (JP 2015-166204 A), there is described a control apparatus for a vehicle that makes an upper limit of a state of charge (hereinafter called as an SOC) of a battery larger than a normal upper limit and that controls an operating point of an engine to a target operating point at which the engine operates at high efficiency, when there is a surplus charging power in the battery, in the case where it is determined that there is a request for heating. This control apparatus sets the upper limit of the SOC of the battery to the normal upper limit and controls the operating point of the engine to a target operating point that is defined as an operating point at which the engine operates at low efficiency, when there is no surplus charging power in the battery, in the case where it is determined that there is a request for heating. By controlling the operating point of the engine to the target operating point that is defined as the operating point at which the engine operates at low efficiency, the amount of exhaust heat of the engine increases, so heating operation can be performed through the use of exhaust heat of the engine.

### SUMMARY

However, in the control apparatus for the vehicle described in Japanese Patent Application Publication No. 2015-166204 (JP 2015-166204 A), the operating point of the engine is controlled without detecting a load state of the engine. Therefore, according to the control apparatus for the vehicle described in Japanese Patent Application Publication No. 2015-166204 (JP 2015-166204 A), a deterioration in fuel consumption or electric power consumption of the vehicle may be caused due to the surplus generation of exhaust heat of the engine, by controlling the operating point of the engine to the target operating point that is defined as the operating point at which the engine operates at low efficiency despite the operation of the engine in a load state where exhaust heat capable of sufficiently providing energy required for heating operation is generated.

The disclosure has been made in view of the aforementioned problem. The disclosure provides a control apparatus for a vehicle and a control method for the vehicle that make it possible to restrain a deterioration in fuel consumption or electric power consumption from being caused due to the surplus generation of exhaust heat of an engine at the time of heating operation.

Thus, according to one aspect of the disclosure, there is provided a control apparatus for a vehicle. The vehicle includes a heating device that heats an interior of the vehicle through use of at least one of exhaust heat of an engine or an electric power of a battery, and runs only through use of the electric power of the battery and through use of an output of the engine and the electric power of the battery. The control apparatus is equipped with an electronic control unit that is configured to: (i) when a heating operation is executed, control an operating point of the engine to a target operating point that is defined as a same operating point of the engine as at a time of normal operation when the heating operation is not performed, when the engine operates in a high-load region; and (ii) when a heating operation is executed, control the operating point of the engine to a target operating point that is defined as an operating point of the engine at which the output of the engine is larger than at the time of normal operation, when the engine operates in a low-load region or an intermediate-load region.

Besides, in the control apparatus, the electronic control unit may be configured to increase a load of the engine while holding a rotational speed of the engine constant, when the engine operates in the low-load region. The control apparatus as described above makes it possible to restrain noise and vibrations from being generated by the engine due to an increase in rotational speed of the engine.

Besides, in the control apparatus, the electronic control unit may be configured to: (i) when a charge amount of the battery becomes smaller than a predetermined value while the vehicle is stopped, heat the vehicle interior through use of exhaust heat of the engine by driving the engine; and (ii) when the charge amount of the battery becomes smaller than the predetermined value while the vehicle is stopped, control the operating point of the engine to a target operating point that is defined as an operating point of the engine at which the load of the engine is higher than at the time of normal operation. The control apparatus as described above makes it possible to maintain the heating performance even while the vehicle is stopped.

Besides, in the control apparatus, the electronic control unit may be configured to: (i) predict a load of the engine on a running route of the vehicle; and (ii) control the operating point of the engine in accordance with a transition of the predicted load. The control apparatus as described above makes it possible to restrain a deterioration in fuel consumption or electric power consumption of the vehicle from being caused due to the surplus generation of exhaust heat of the engine when the vehicle runs along the running route.

According to another aspect of the disclosure, there is provided a control method for a vehicle. The vehicle has a heating device that is configured to heat an interior of the vehicle through use of at least one of exhaust heat of an engine or an electric power of a battery, and runs only through use of the electric power of the battery and through use of an output of the engine and the electric power of the battery. In the control method: (i) when a heating operation is executed, an operating point of the engine is controlled to a target operating point that is defined as a same operating point of the engine as at a time of normal operation when the heating operation is not performed, when the engine operates in a high-load region; and (ii) when the heating operation is executed, the operating point of the engine is controlled to a target operating point that is defined as an operating point of the engine at which the output of the engine is larger than at the time of normal operation, when the engine operates in a low-load region or an intermediate-load region.

In the control apparatus for the vehicle according to the disclosure and the control method for the vehicle according to the disclosure, when the heating operation is executed, the operating point of the engine is controlled to the target operating point that is defined as the same operating point of the engine as at the time of normal operation when heating operation is not performed, in the case where the engine operates in the high-load region. Moreover, when the heating operation is executed, the operating point of the engine is controlled to the target operating point that is defined as the operating point of the engine at which the output of the engine is larger than at the time of normal operation, in the case where the engine operates in the low-load region or the intermediate-load region. Thus, a deterioration in fuel consumption or electric power consumption of the vehicle can be restrained from being caused due to the surplus generation of exhaust heat of the engine, by controlling the operating point of the engine to the target operating point that is defined as the operating point at which the engine operates at low efficiency despite the operation of the engine in the load sate where exhaust heat capable of sufficiently providing energy required for heating operation is generated.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is a block diagram showing the configuration of a vehicle to which a control apparatus for the vehicle according to one of the embodiments as an example of the disclosure is applied;

FIG. 2 is a block diagram showing the configuration of a heating device that is mounted in the vehicle shown in FIG. 1;

FIG. 3A is a timing chart for illustrating the operation of the heating device shown in FIG. 2;

FIG. 3B is a block diagram showing an engine coolant flow when a heat pump independent operation for heating a vehicle interior only through the use of a heat pump is performed;

FIG. 3C is a block diagram showing the engine coolant flow when an engine coolant cooperative operation of the heat pump and engine coolant are performed;

FIG. 4 is a block diagram showing the configuration of the control apparatus for the vehicle according to one of the embodiments as the example of the disclosure;

FIG. 5 is a flowchart showing the flow of a heating control process according to the first embodiment of the disclosure;

FIG. 6 is a flowchart showing the flow of a heating control process according to the second embodiment of the disclosure;

FIG. 7 is a flowchart showing the flow of a heating control process according to the third embodiment of the disclosure;

FIG. 8A is a view for illustrating the heating control process according to the third embodiment of the disclosure, the view showing examples of a driving force required by a driver, a difference in engine rotational speed, and a difference in engine load that correspond to an operating point of an engine;

FIG. 8B is a view for illustrating the heating control process according to the third embodiment of the disclosure, the view showing an example of the operating point of the engine at the time of normal operation and at the time of heating operation; and

FIG. 9 is a flowchart showing the flow of a heating control process according to the fourth embodiment of the disclosure.

### DETAILED DESCRIPTION OF EMBODIMENTS

The configuration of a control apparatus for a vehicle according to one of the embodiments as an example of the disclosure will be described hereinafter with reference to the drawings.

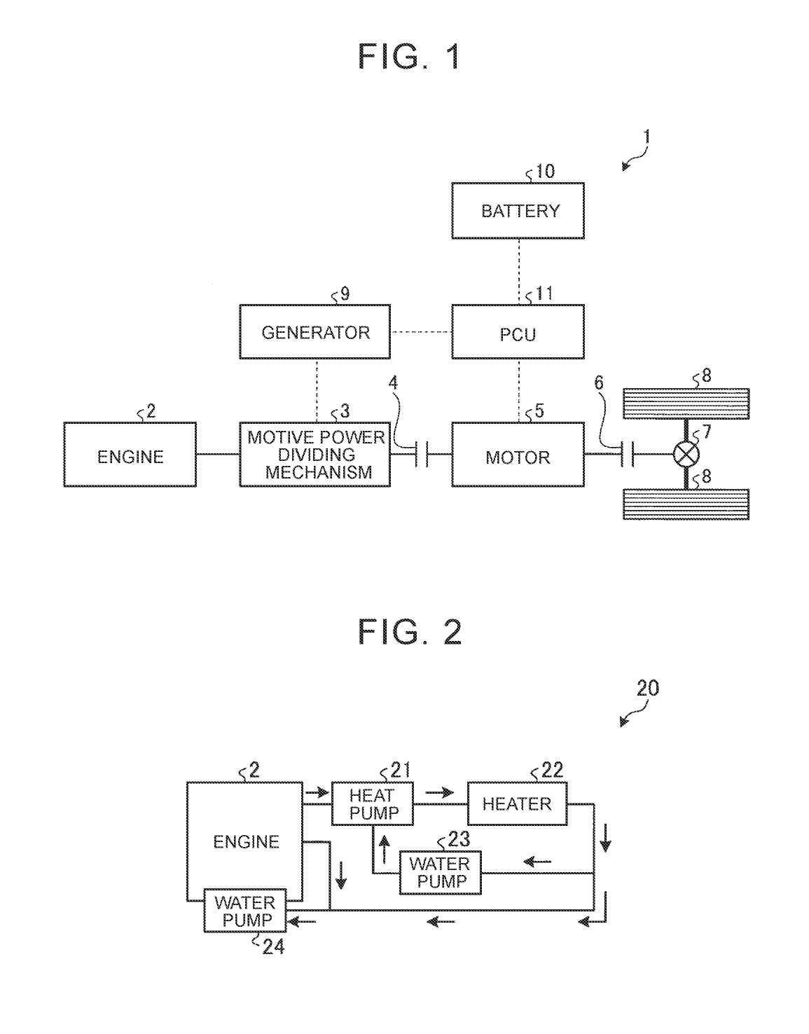

First of all, the configuration of the vehicle to which the control apparatus for the vehicle according to one of the embodiments as the example of the disclosure is applied will be described with reference to FIG. 1.

FIG. 1 is a block diagram showing the configuration of the vehicle to which the control apparatus for the vehicle according to one of the embodiments as the example of the disclosure is applied. As shown in FIG. 1, a vehicle 1 to which the control apparatus for the vehicle according to one of the embodiments as the example of the disclosure is applied is configured as a vehicle that can run only through the use of an electric power of a battery (EV running) and through the use of an output of an engine and the electric power of the battery (HV running), such as a plug-in hybrid vehicle (a PHV), a range-extended electric vehicle (an REEV) or the like.

The vehicle 1 is equipped with an engine 2, a motive power dividing mechanism 3, a clutch 4, a motor 5, a clutch 6, a differential gear 7, driving wheels 8, a generator 9, a battery 10, and a power control unit (a PCU) 11 as main components.

The engine 2 is configured as an internal combustion engine such as a gasoline engine, a diesel engine or the like. The engine 2 outputs a driving torque for causing the vehicle 1 to run.

The motive power dividing mechanism 3 is configured as, for example, a planetary gear mechanism. The motive power dividing mechanism 3 is configured to be able to divide a motive power transmission path into a motive power transmission path through which an output of the engine is transmitted to the driving wheel 8 sides via the clutch 4, and a motive power transmission path through which the output of the engine is transmitted to the generator 9 side.

The motor 5 is configured as, for example, a three-phase AC (alternating current) electric motor. The motor 5 has the function of transmitting a driving force to the driving wheels 8 via the clutch 6 and the differential gear 7 through the use of the electric power of the battery 10. Besides, the motor 5 also functions as a generator (an electric power generation device) that generates electric power by being driven at the time of running through the use of the output of the engine or at the time of braking of the vehicle 1. The electric power generated by the motor 5 is supplied to the battery 10 via the PCU 11.

The generator 9 functions as a generator that generates electric power through the use of the output of the engine divided by the motive power dividing mechanism 3. The electric power generated by the generator 9 is supplied to the battery 10 via the PCU 11.

The battery 10 is configured as a secondary battery such as a nickel hydride battery, a lithium-ion battery or the like. Instead of being charged with the electric power generated by the motor 5 and/or the generator 9, the battery 10 may be charged with the electric power supplied from an external electric power supply. Incidentally, the battery 10 may not necessarily be a secondary battery but may be any electric power storage device that can generate a DC (direct current) voltage and that can be charged. For example, the battery 10 may be a capacitor or the like.

The PCU 11 has the function of converting a DC electric power that is supplied from the battery 10 into an AC electric power and driving the motor 5. Besides, the PCU 11 has the function of converting an AC electric power generated by the motor 5 and the generator 9 into a DC electric power and charging the battery 10 therewith.

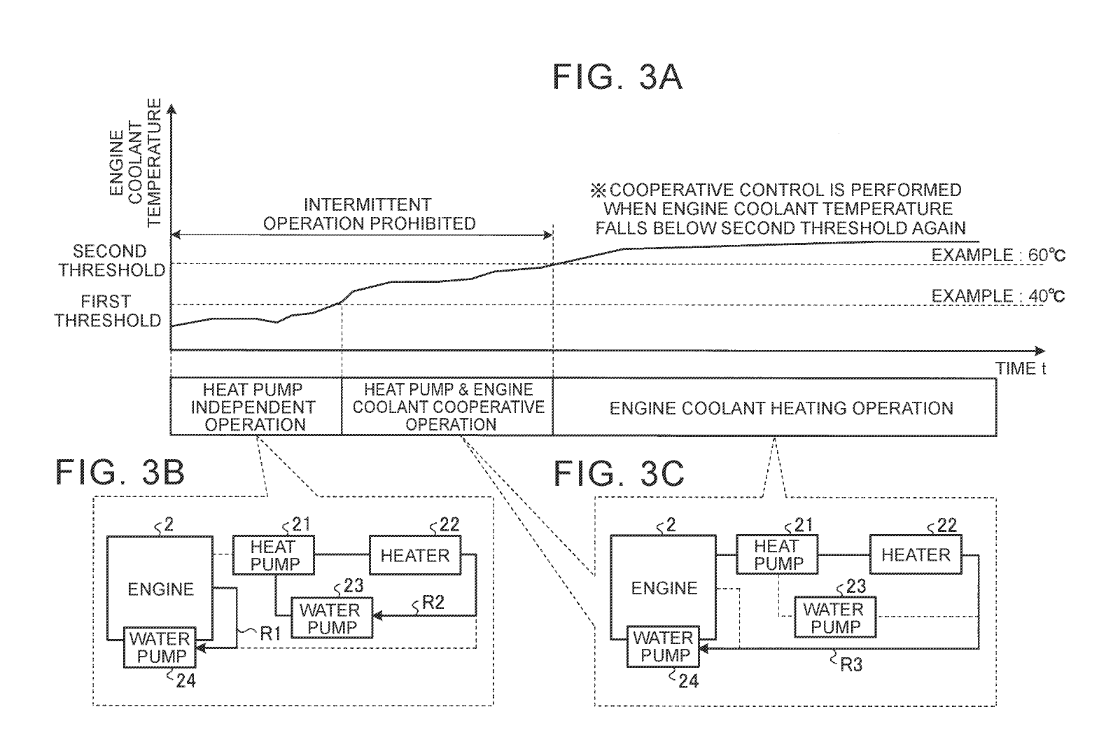

Next, the configuration of a heating device 20 that is mounted in the aforementioned vehicle 1 will be described with reference to FIGS. 2, 3A, 3B and 3C. FIG. 2 is a block diagram showing the configuration of the heating device 20 that is mounted in the vehicle 1 shown in FIG. 1. FIG. 3A is a timing chart for illustrating the operation of the heating device 20 shown in FIG. 2.

As shown in FIG. 2, the heating device 20 that is mounted in the vehicle 1 is a device that heats a vehicle interior through the use of at least one of the exhaust heat of the engine 2 and the electric power of the battery 10. The heating device 20 is equipped with a heat pump 21, a heater 22, a water pump 23 and a water pump 24 as main components.

The heat pump 21 heats engine coolant supplied from the engine 2 and the water pump 23 by exchanging heat between a cooling medium and engine coolant through pressurization, compression and adiabatic expansion of the cooling medium with the aid of the electric power of the battery 10.

The heater 22 has a heater core that exchanges heat between the air in the vehicle interior and the engine coolant discharged from the heat pump 21. The heater 22 heats the vehicle interior by delivering the air in the vehicle interior to the heater core and exchanging heat between the air in the vehicle interior and the engine coolant discharged from the heat pump 21 in the heater core.

The water pump 23 force-feeds the engine coolant discharged from the heater 22 to the heat pump 21. The water pump 24 force-feeds the engine coolant discharged from the heater 22 to the engine 2 and the heat pump 21 in this order.

In the heating device 20 thus configured, as shown in FIGS. 3A and 3B, when the temperature of engine coolant is lower than a first threshold (e.g., 40° C.), it is difficult to heat the vehicle interior by engine coolant. Therefore, engine coolant is circulated into an engine coolant flow channel R1 and an engine coolant flow channel R2. In the engine coolant flow channel R1, engine coolant circulates between the engine 2 and the water pump 24. In the engine coolant flow channel R2, engine coolant circulates among the heat pump 21, the heater 22 and the water pump 23. Then, heat pump independent operation for heating the vehicle interior only through the use of the heat pump 21 is performed by driving the heat pump 21.

On the other hand, as shown in FIGS. 3A and 3C, when the temperature of engine coolant is equal to or higher than the first threshold and lower than a second threshold (e.g., 60° C.), the temperature of engine coolant rises, and the vehicle interior can be heated through the use of engine coolant, so engine coolant is circulated into an engine coolant flow channel R3. In the engine coolant flow channel R3, engine coolant circulates among the engine 2, the heat pump 21, the heater 22 and the water pump 24. Then, heat pump & engine coolant cooperative operation for heating the vehicle interior through the use of both engine coolant and the heat pump 21 is performed by driving the heat pump 21. Incidentally, while heat pump independent operation and heat pump & engine coolant cooperative operation are performed, intermittent operation as repetition of the operation and stop of the engine 2 at appropriate timings is prohibited.

Besides, as shown in FIGS. 3A and 3C, when the temperature of engine coolant is equal to or higher than the second threshold, the vehicle interior can be heated only through the use of engine coolant, so engine coolant is circulated into the engine coolant flow channel R3. In the engine coolant flow channel R3, engine coolant circulates among the engine 2, the heat pump 21, the heater 22 and the water pump 24. Then, engine coolant heating operation for heating the vehicle interior only through the use of engine coolant by stopping the driving of the heat pump 21 is performed. Incidentally, when the temperature of engine coolant becomes lower than the second threshold in performing engine coolant heating operation, heat pump & engine coolant cooperative operation is performed. Besides, while engine coolant heating operation is performed, intermittent operation as repetition of the operation and stop of the engine 2 at appropriate timings is permitted.

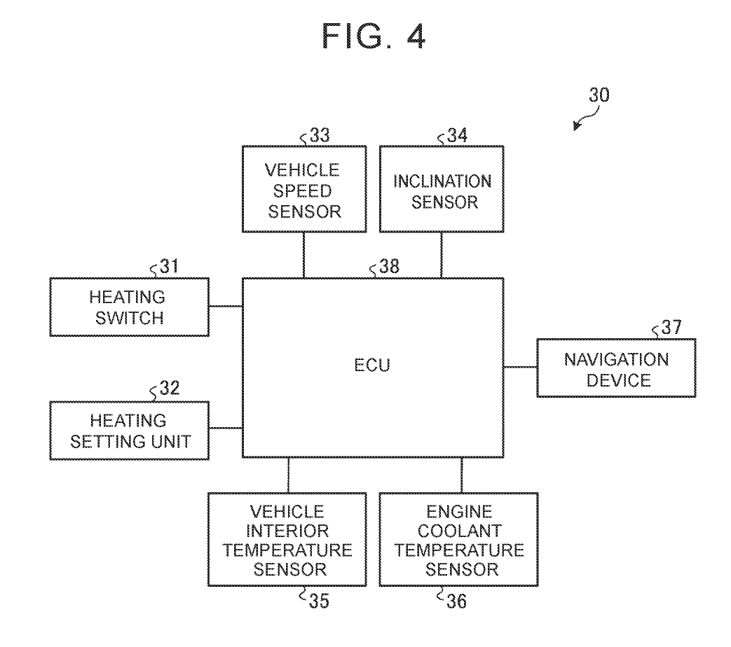

Next, the configuration of a control apparatus 30 for the vehicle according to one of the embodiments as the example of the disclosure will be described with reference to FIG. 4.

FIG. 4 is a block diagram showing the configuration of the control apparatus 30 for the vehicle according to one of the embodiments as the example of the disclosure. As shown in FIG. 4, the control apparatus 30 for the vehicle according to one of the embodiments as the example of the disclosure is equipped with a heating switch 31, a heating setting unit 32, a vehicle speed sensor 33, an inclination sensor 34, a vehicle interior temperature sensor 35, an engine coolant temperature sensor 36, a navigation device 37 and an electronic control unit (an ECU) 38 as main components.

The heating switch 31 is configured as an operator for turning the heating device 20 on/off. The heating switch 31 outputs an electric signal, which indicates whether the heating device 20 is on or off (whether or not there is a request for heating) in accordance with the operation of the operator, to the ECU 38.

The heating setting unit 32 is configured as an operator for setting the temperature of the vehicle interior. The heating setting unit 32 outputs an electric signal, which indicates a temperature of the vehicle interior set in accordance with the operation of the operator, to the ECU 38.

The vehicle speed sensor 33 detects a speed of the vehicle 1 (a vehicle speed), and outputs an electric signal indicating the detected vehicle speed to the ECU 38.

The inclination sensor 34 detects an angle of inclination of the vehicle 1 in a longitudinal direction at a place where the vehicle 1 is located, and outputs an electric signal indicating the detected angle of inclination to the ECU 38.

The vehicle interior temperature sensor 35 detects a temperature of the vehicle interior and outputs an electric signal indicating the detected temperature of the vehicle interior to the ECU 38.

The engine coolant temperature sensor 36 detects a temperature of engine coolant, and outputs an electric signal indicating the detected temperature of engine coolant to the ECU 38.

The navigation device 37 is configured as a common route guidance device. The navigation device 37 outputs information on a speed limit, an angle of inclination and the like of a route (a running route) to be followed by the vehicle 1 to the ECU 38.

The ECU 38 is mainly configured as a microcomputer that is equipped with a central processing unit (a CPU), a read only memory (a ROM), a random access memory (a RAM) and the like. The ECU 38 performs various control processes including a heating control process that will be described later, by executing various control programs that are stored in the ROM.

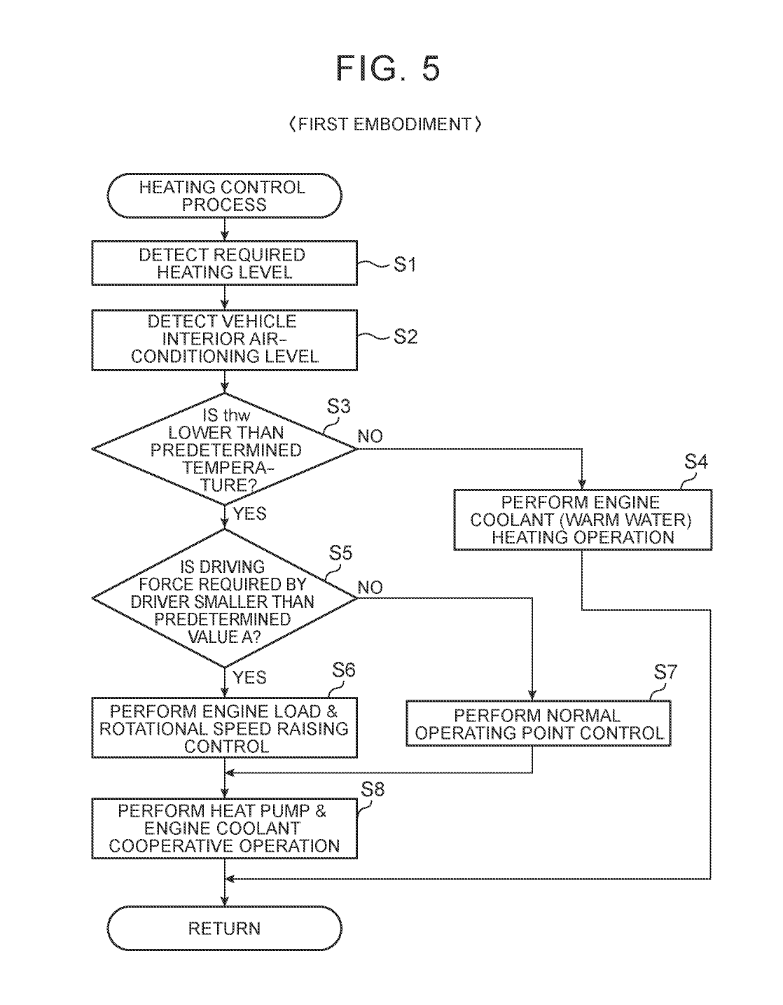

In the control apparatus 30 for the vehicle thus configured, the ECU 38 performs the following heating control process, thereby restraining a deterioration in fuel consumption or electric power consumption from being caused due to the surplus generation of exhaust heat of the engine 2 at the time of heating operation. The operation of the ECU 38 in performing the heating control process according to the first to fourth embodiments of the disclosure will be described hereinafter with reference to FIGS. 5 to 9.

First of all, the operation of the ECU 38 in performing the heating control process according to the first embodiment of the disclosure will be described with reference to FIG. 5. FIG. 5 is a flowchart showing the flow of the heating control process according to the first embodiment of the disclosure. The flowchart shown in FIG. 5 is started at a timing when the heating device 20 is turned on through the operation of the heating switch 31 by a passenger of the vehicle 1, and the heating control process proceeds to a processing of step S1. Incidentally, this heating control process is repeatedly performed while the heating device 20 is on.

In the processing of step S1, the ECU 38 detects a temperature of the vehicle interior (a required heating level) that is required through the use of an electric signal that is output from the heating setting unit 32. Thus, the processing of step S1 is completed, and the heating control process proceeds to a processing of step S2.

In the processing of step S2, the ECU 38 detects a temperature of the vehicle interior (a vehicle interior air-conditioning level) through the use of an electric signal that is output from the vehicle interior temperature sensor 35. Thus, the processing of step S2 is completed, and the heating control process proceeds to a processing of step S3.

In the processing of step S3, the ECU 38 detects a temperature thw of engine coolant through the use of an electric signal that is output from the engine coolant temperature sensor 36, and determines whether or not the detected temperature thw of engine coolant is lower than a predetermined temperature (e.g., 60° C.). If the temperature thw of engine coolant is lower than the predetermined temperature as a result of the determination (Yes in step S3), the ECU 38 causes the heating control process to proceed to a processing of step S5. On the other hand, if the temperature thw of engine coolant is equal to or higher than the predetermined temperature (No in step S3), the ECU 38 causes the heating control process to proceed to a processing of step S4.

In the processing of step S4, the ECU 38 performs engine coolant (warm water) heating operation such that the vehicle interior air-conditioning level detected in the processing of step S2 becomes equal to the required heating level detected in the processing of step S1. That is, the ECU 38 stops the operation of the heat pump 21 and heats the vehicle interior only through the use of engine coolant. Thus, the processing of step S4 is completed, and the heating control process returns to the processing of step S1.

In the processing of step S5, first of all, the ECU 38 detects a vehicle speed based on an electric signal that is output by the vehicle speed sensor 33, and detects an angle of inclination of the vehicle 1 in the longitudinal direction based on an electric signal that is output by the inclination sensor 34. Subsequently, the ECU 38 reads out a required value of the output of the engine corresponding to the detected vehicle speed and the detected angle of inclination, as a driving force required by a driver, from a map indicating how the vehicle speed and the angle of inclination are related to the required value of the output of the engine. Then, the ECU 38 determines whether or not the driving force required by the driver is smaller than a predetermined value A. It should be noted herein that the predetermined value A corresponds to a required value (e.g., equal to or larger than 25 (kW)) of the output of the engine at which the temperature of engine coolant is not prevented from rising even when heating operation is performed through the use of the engine coolant warmed by exhaust heat of the engine 2, in other words, a required value of the output of the engine at the time when the engine 2 operates in a high-load state. If the driving force required by the driver is smaller than the predetermined value A as a result of the determination (Yes in step S5), the ECU 38 causes the heating control process to proceed to a processing of step S6. On the other hand, if the driving force required by the driver is equal to or larger than the predetermined value A (No in step S5), the ECU 38 causes the heating control process to proceed to a processing of step S7.

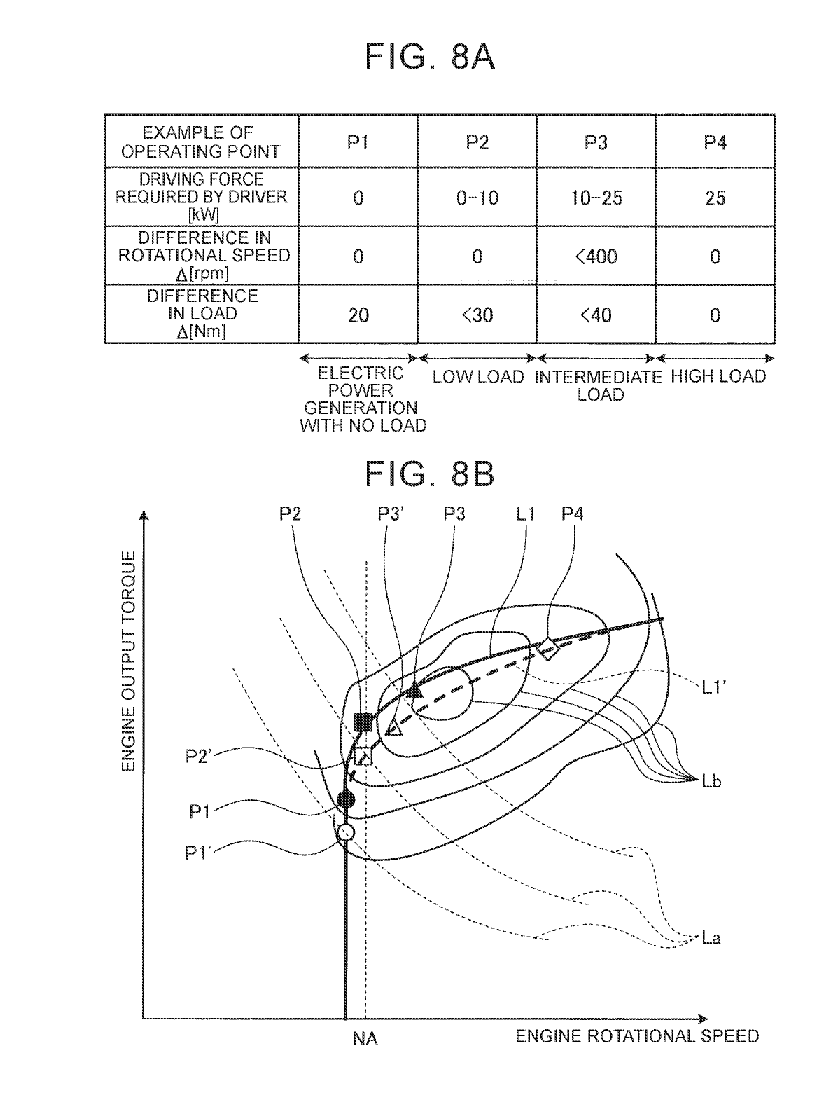

In the processing of step S6, the ECU 38 determines that the engine 2 does not operate in the high-load state, and controls an operating point of the engine 2 to a target operating point that is defined as an operating point of the engine 2 at which the load and rotational speed of the engine 2 are higher than at the time of normal operation when heating operation is not performed. As a result, the output of the engine increases to become larger than at the time of normal operation when heating operation is not performed, so a large amount of thermal energy can be produced. Incidentally, in the present embodiment of the disclosure, “the operating point of the engine 2” means an operating point indicating an operating state of the engine 2 in a two-dimensional coordinate system whose coordinate axes represent state quantities indicating the operating state of the engine 2 as exemplified by the rotational speed of the engine, the output torque (load) of the engine or the like (see FIG. 8B). Thus, the processing of step S6 is completed, and the heating control process proceeds to a processing of step S8.

In the processing of step S7, the ECU 38 determines that the engine 2 operates in the high-load state, and controls the operating point of the engine 2 to a target operating point that is defined as the same operating point of the engine 2 as at the time of normal operation when heating operation is not performed. Thus, the processing of step S7 is completed, and the heating control process proceeds to the processing of step S8.

In the processing of step S8, the ECU 38 performs heat pump & engine coolant cooperative operation such that the vehicle interior air-conditioning level detected in the processing of step S2 becomes equal to the required heating level detected in the processing of step S1. That is, the ECU 38 heats the vehicle interior through the use of both the heat pump 21 and engine coolant. Thus, the processing of step S8 is completed, and the heating control process returns to the processing of step S1.

As is apparent from the foregoing description, in the heating control process according to the first embodiment of the disclosure, when the engine 2 operates in the high-load region, the ECU 38 controls the operating point of the engine 2 to the target operating point that is defined as the same operating point of the engine 2 as at the time of normal operation when heating operation is not performed. Thus, a deterioration in fuel consumption or electric power consumption of the vehicle 1 can be restrained from being caused due to the surplus generation of exhaust heat of the engine 2, by controlling the operating point of the engine 2 to the target operating point that is defined as an operating point at which the engine operates at low efficiency despite the operation of the engine 2 in the high-load state where exhaust heat capable of sufficiently providing energy required for heating operation is generated.

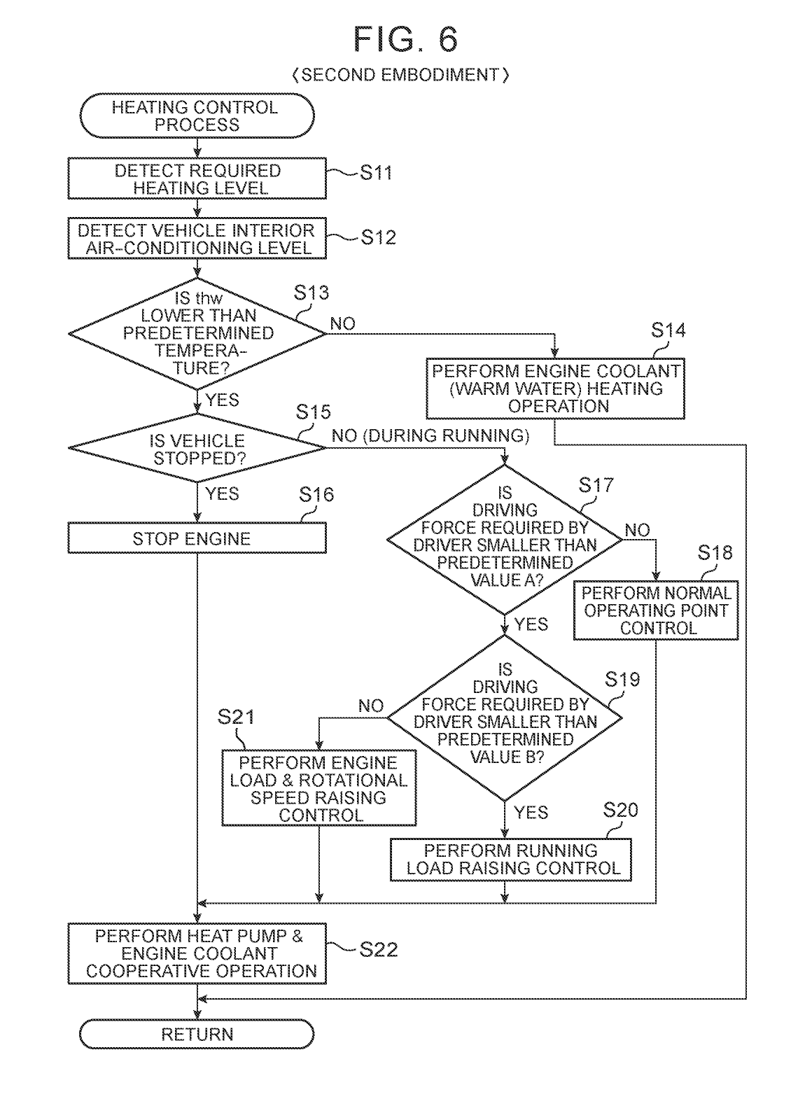

Next, the operation of the ECU 38 in performing the heating control process according to the second embodiment of the disclosure will be described with reference to FIG. 6. FIG. 6 is a flowchart showing the flow of the heating control process according to the second embodiment of the disclosure. The flowchart shown in FIG. 6 is started at a timing when the heating device 20 is turned on through the operation of the heating switch 31 by the passenger of the vehicle 1, and the heating control process proceeds to a processing of step S11. Incidentally, this heating control process is repeatedly performed while the heating device 20 is turned on. Besides, the processing contents of steps S1 1 to S14 shown in FIG. 6 are identical to the processing contents of steps S1 to S4 shown in FIG. 5, so the description thereof will be omitted hereinafter and the description of a processing of step S15 will be given first.

In the processing of step S15, the ECU 38 detects a vehicle speed based on an electric signal that is output by the vehicle speed sensor 33, and determines, based on the detected vehicle speed, whether or not the vehicle 1 is stopped. If the vehicle 1 is stopped as a result of the determination (Yes in step S15), the ECU 38 causes the heating control process to proceed to a processing of step S16. On the other hand, if the vehicle 1 is running (No in step S15), the ECU 38 causes the heating control process to proceed to a processing of step S17.

In the processing of step S16, the ECU 38 stops the operation of the engine 2. Thus, the processing of step S16 is completed, and the heating control process proceeds to a processing of step S22.

In the processing of step S17, first of all, the ECU 38 detects a vehicle speed based on an electric signal that is output by the vehicle speed sensor 33, and detects an angle of inclination of the vehicle 1 in the longitudinal direction based on an electric signal that is output by the inclination sensor 34. Subsequently, the ECU 38 reads out a required value of the output of the engine corresponding to the detected vehicle speed and the detected angle of inclination, as a driving force required by the driver, from a map indicating how the vehicle speed and the angle of inclination are related to the required value of the output of the engine. Then, the ECU 38 determines whether or not the driving force required by the driver is smaller than the predetermined value A. If the driving force required by the driver is smaller than the predetermined value A as a result of the determination (Yes in step S17), the ECU 38 causes the heating control process to proceed to a processing of step S19. On the other hand, if the driving force required by the driver is equal to or larger than the predetermined value A (No in step S17), the ECU 38 causes the heating control process to proceed to a processing of step S18.

In the processing of step S18, the ECU 38 determines that the engine 2 operates in the high-load state, and controls the operating point of the engine 2 to a target operating point that is defined as the same operating point of the engine 2 as at the time of normal operation when heating operation is not performed. Thus, the processing of step S18 is completed, and the heating control process proceeds to the processing of step S22.

In the processing of step S19, the ECU 38 determines whether or not the driving force required by the driver, which has been read out in the processing of step S17, is smaller than a predetermined value B. It should be noted herein that the predetermined value B corresponds to a required value (e.g., within a range of 10 9to 25 (kW)) of the output of the engine at which the temperature of engine coolant does not rise or falls (e.g., the amount of heat dissipation is smaller than 1 (kW)) when heating operation is performed through the use of the engine coolant warmed by exhaust heat of the engine 2, in other words, a required value of the output of the engine at the time when the engine 2 operates in an intermediate-load region. If the driving force required by the driver is smaller than the predetermined value B as a result of the determination (Yes in step S19), the ECU 38 causes the heating control process to proceed to a processing of step S20. On the other hand, if the driving force required by the driver is equal to or larger than the predetermined value B (No in step S19), the ECU 38 causes the heating control process to proceed to a processing of step S21.

In the processing of step S20, the ECU 38 determines that the engine 2 operates in a low-load state, and controls the operating point of the engine 2 such that the load of the engine 2 increases while maintaining the rotational speed of the engine 2 at the operating point of the engine 2 at the time of normal operation when heating operation is not performed. As a result, while restraining noise and vibrations from being generated by the engine due to an increase in the rotational speed of the engine 2, the output of the engine can be increased to be made larger than when the heating device 20 is not on, and a large amount of thermal energy can be produced. Incidentally, the low-load state means a load state of the engine 2 where the temperature of engine coolant significantly falls (e.g., the amount of heat dissipation is equal to or larger than 1 (kw)) when heating operation is performed through the use of the engine coolant warmed by exhaust heat of the engine 2. Thus, the processing of step S20 is completed, and the heating control process proceeds to the processing of step S22.

In the processing of step S21, the ECU 38 determines that the engine 2 operates in an intermediate-load state, and controls the operating point of the engine 2 to a target operating point that is defined as a target point of the engine 2 at which the load and rotational speed of the engine 2 are higher than at the time of normal operation when heating operation is not performed. As a result, the output of the engine can be increased to be made larger than when the heating device 20 is not on, and a large amount of thermal energy can be produced. Incidentally, the ECU 38 may change the rotational speed of the engine 2 in accordance with the magnitude of the driving force required by the driver. Thus, the processing of step S21 is completed, and the heating control process proceeds to the processing of step S22.

In the processing of step S22, the ECU 38 performs heat pump & engine coolant cooperative operation such that the vehicle interior air-conditioning level detected in the processing of step S12 becomes equal to the required heating level detected in the processing of step S11. That is, the ECU 38 heats the vehicle interior through the use of both the heat pump 21 and engine coolant. Thus, the processing of step S22 is completed, and the heating control process returns to the processing of step S11.

As is apparent from the foregoing description, in the heating control process according to the second embodiment of the disclosure, the ECU 38 increases the load of the engine 2 while holding the rotational speed of the engine 2 constant when the engine 2 operates in the low-load state. According to this configuration, an effect of making it possible to restrain noise and vibrations from being generated by the engine due to an increase in the rotational speed of the engine 2 can be achieved, in addition to the effect that is obtained by the heating control process according to the above-mentioned first embodiment of the disclosure.

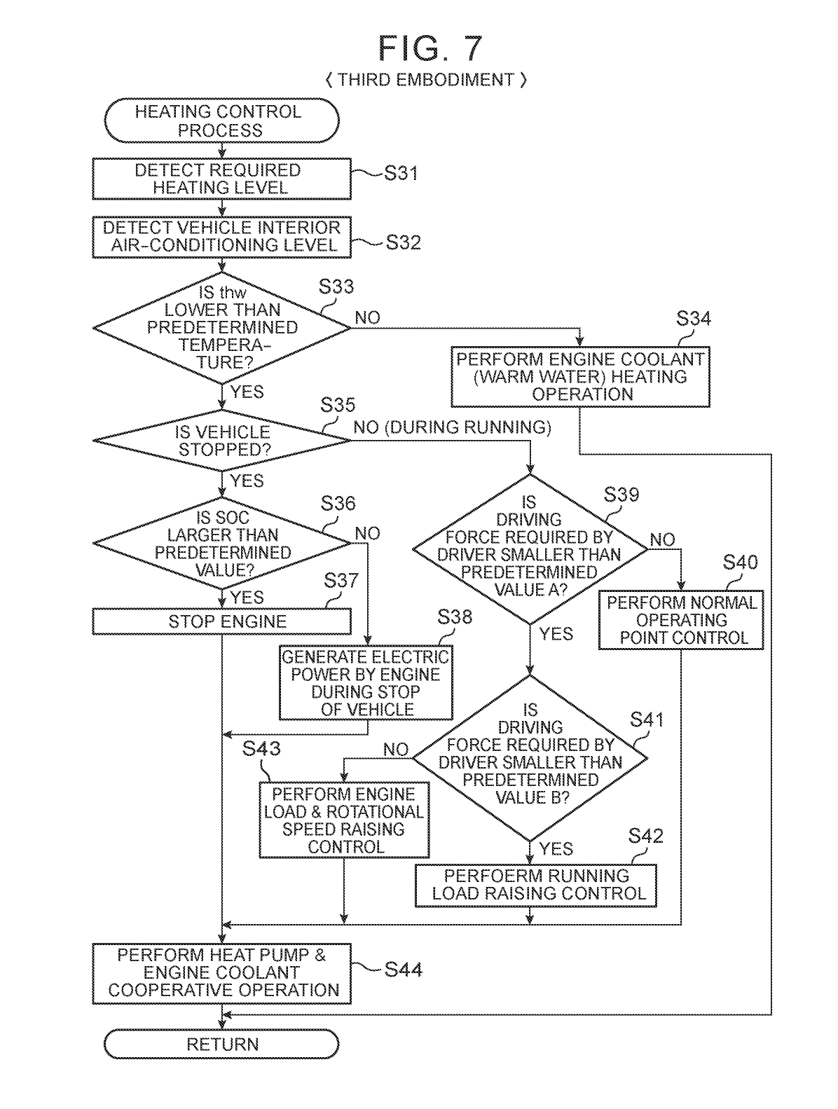

Next, the operation of the ECU 38 in performing the heating control process according to the third embodiment of the disclosure will be described with reference to FIGS. 7, 8A and 8B. FIG. 7 is a flowchart showing the flow of the heating control process according to the third embodiment of the disclosure. FIGS. 8A and 8B are a view for illustrating the heating control process according to the third embodiment of the disclosure. FIG. 8A is a view showing examples of the driving force required by the driver, the difference in engine rotational speed and the difference in engine load corresponding to operating points P1 to P4 of the engine shown in FIG. 8B. FIG. 8B is a view showing an example of the operating point of the engine 2 at the time of normal operation and at the time of heating operation.

The flowchart shown in FIG. 7 is started at a timing when the heating device 20 is turned on through the operation of the heating switch 31 by the passenger of the vehicle 1, and the heating control process proceeds to a processing of step S31. Incidentally, this heating control process is repeatedly performed while the heating device 20 is on. Besides, the processing contents of steps S31 to S34 shown in FIG. 7 are identical to the processing contents of steps S11 to S14 shown in FIG. 6, so the description thereof will be omitted hereinafter and the description of a processing of step S35 will be given first.

In the processing of step S35, the ECU 38 detects a vehicle speed based on an electric signal that is output by the vehicle speed sensor 33, and determines, based on the detected vehicle speed, whether or not the vehicle 1 is stopped. If the vehicle 1 is stopped as a result of the determination (Yes in step S35), the ECU 38 causes the heating control process to proceed to a processing of step S36. On the other hand, if the vehicle 1 is running (No in step S35), the ECU 38 causes the heating control process to proceed to a processing of step S39.

In the processing of step S36, the ECU 38 detects a charge amount (that is an SOC) of the battery 10 via the PCU 11, and determines whether or not the detected SOC is larger than a predetermined value. The predetermined value corresponds to a third predetermined value according to the disclosure. If the SOC is larger than the predetermined value as a result of the determination (Yes in step S36), the ECU 38 causes the heating control process to proceed to a processing of step S37. On the other hand, if the SOC is equal to or smaller than the predetermined value (No in step S36), the ECU 38 causes the heating control process to proceed to a processing of step S38.

In the processing of step S37, the ECU 38 stops the operation of the engine 2. Thus, the processing of step S37 is completed, and the heating control process proceeds to a processing of step S44.

In the processing of step S38, the ECU 38 charges the battery 10 by driving the generator 9 by the output of the engine, and controls the operating point of the engine 2 such that the load of the engine 2 increases while maintaining the rotational speed of the engine 2 at the operating point of the engine 2 at the time of normal operation when heating operation is not performed. In concrete terms, as shown in FIGS. 8A and 8B, the ECU 38 increases the load of the engine 2 by about 20 (Nm) while maintaining the rotational speed of the engine 2, by controlling the operating point of the engine 2 from an operating point P1′ at the time of normal operation to the operating point P1. Incidentally, in FIG. 8B, L1 denotes an operating line of the engine 2 at the time when the heating control process is performed (heating is on), L1′ denotes an operating line of the engine 2 at the time of normal operation (heating is off), La denotes an iso-load curve of the engine 2 (which is proportional to the vehicle speed), and Lb denotes an iso-efficiency curve of the engine 2. Thus, the processing of step S38 is completed, and the heating control process proceeds to the processing of step S44.

In the processing of step S39, first of all, the ECU 38 detects a vehicle speed based on an electric signal that is output by the vehicle speed sensor 33, and detects an angle of inclination of the vehicle 1 in the longitudinal direction based on an electric signal that is output by the inclination sensor 34. Subsequently, the ECU 38 reads out a driving force of the vehicle 1 corresponding to the detected vehicle speed and the detected angle of inclination, as a driving force required by the driver, from a map indicating how the vehicle speed and the angle of inclination are related to the driving force of the vehicle 1. Then, the ECU 38 determines whether or not the driving force required by the driver is smaller than the predetermined value A. If the driving force required by the driver is smaller than the predetermined value A as a result of the determination (Yes in step S39), the ECU 38 causes the heating control process to proceed to a processing of step S41. On the other hand, if the driving force required by the driver is equal to or larger than the predetermined value A (No in step S39), the ECU 38 causes the heating control process to proceed to a processing of step S40.

In the processing of step S40, the ECU 38 determines that the engine 2 operates in the high-load region, and controls the operating point of the engine 2 to a target operating point that is defined as the same operating point of the engine 2 as at the time of normal operation when heating operation is not performed. In concrete terms, as shown in FIG. 8B, the ECU 38 controls the operating point of the engine 2 to the operating point P4 at the time of normal operation. Thus, the processing of step S40 is completed, and the heating control process proceeds to the processing of step S44.

In the processing of step S41, the ECU 38 determines whether or not the driving force required by the driver, which has been read out in the processing of step S39, is smaller than the predetermined value B. If the driving force required by the driver is smaller than the predetermined value B as a result of the determination (Yes in step S41), the ECU 38 causes the heating control process to proceed to a processing of step S42. On the other hand, if the driving force required by the driver is equal to or larger than the predetermined value B (No in step S41), the ECU 38 causes the heating control process to proceed to a processing of step S43.

In the processing of step S42, the ECU 38 determines that the engine 2 operates in the low-load state, and controls the operating point of the engine 2 such that the load of the engine 2 increases while maintaining the rotational speed of the engine 2 at the operating point of the engine 2 at the time of normal operation when heating operation is not performed. In concrete terms, as shown in FIGS. 8A and 8B, the ECU 38 increases the load of the engine 2 by less than 30 (Nm) by controlling the operating point of the engine 2 from an operating point P2′ at the time of normal operation to the operating point P2, while holding the rotational speed of the engine equal to an engine rotational speed NA. Thus, the processing of step S42 is completed, and the heating control process proceeds to the processing of step S44.

In the processing of step S43, the ECU 38 determines that the engine 2 operates in the intermediate-load state, and controls the operating point of the engine 2 to a target operating point that is defined as an operating point of the engine 2 at which the load and rotational speed of the engine 2 are higher than at the time of normal operation when heating operation is not performed. In concrete terms, as shown in FIGS. 8A and 8B, the ECU 38 increases the rotational speed of the engine 2 by less than 400 (rpm) and increases the load of the engine 2 by less than 40 (Nm) by controlling the operating point of the engine 2 from an operating point P3′ at the time of normal operation to the operating point P3. Thus, the processing of step S43 is completed, and the heating control process proceeds to the processing of step S44.

In the processing of step S44, the ECU 38 performs heat pump & engine coolant cooperative operation such that the vehicle interior air-conditioning level detected in the processing of step S32 becomes equal to the required heating level detected in the processing of step S31. That is, the ECU 38 heats the vehicle interior through the use of both the heat pump 21 and engine coolant. Thus, the processing of step S44 is completed, and the heating control process returns to the processing of step S31.

As is apparent from the foregoing description, in the heating control process according to the third embodiment of the disclosure, the ECU 38 heats the vehicle interior through the use of exhaust heat of the engine 2 by driving the engine 2, and controls the operating point of the engine 2 to a target operating point that is defined as an operating point of the engine 2 at which the load of the engine 2 is higher than in the case where there is no request for heating, when the SOC of the battery 10 is equal to or smaller than the predetermined value while the vehicle 1 is stopped. According to this configuration, an effect of making it possible to maintain the heating performance even while the vehicle 1 is stopped can be achieved, in addition to the effects that are obtained by the heating control processes according to the above-mentioned first and second embodiments of the disclosure.

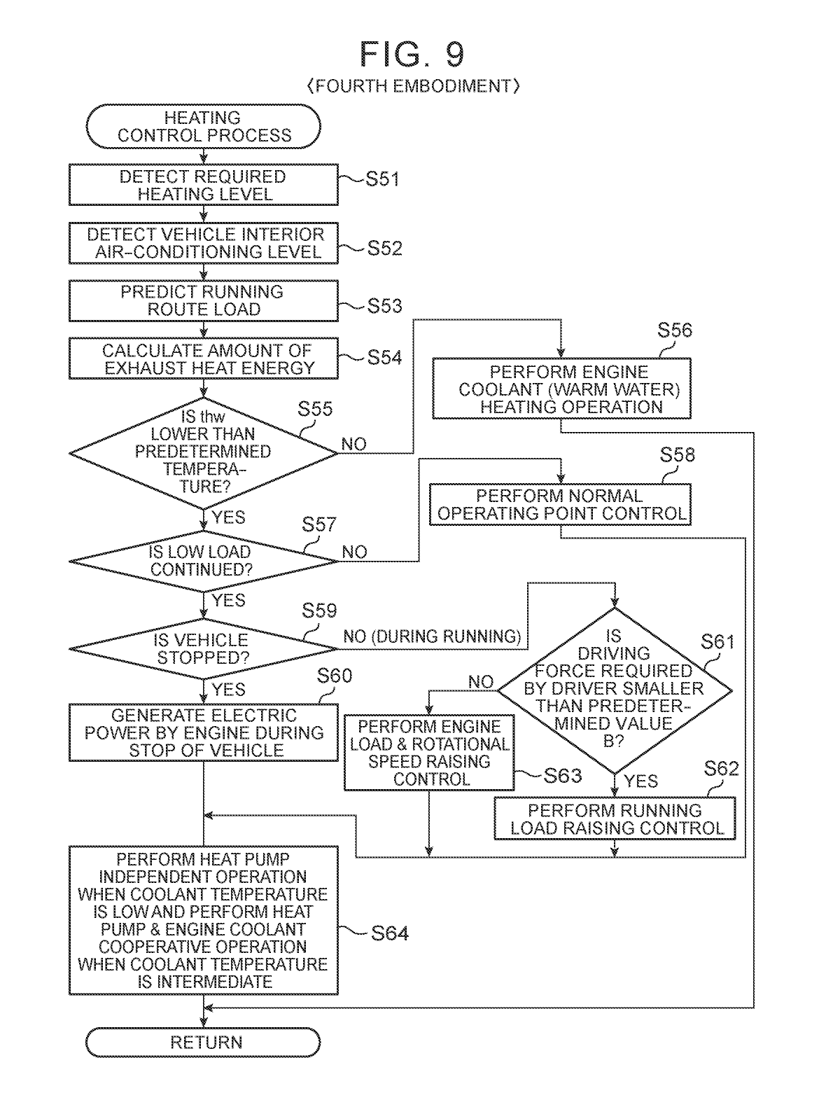

Finally, the operation of the ECU 38 in performing the heating control process according to the fourth embodiment of the disclosure will be described with reference to FIG. 9. FIG. 9 is a flowchart showing the flow of the heating control process according to the fourth embodiment of the disclosure. The flowchart shown in FIG. 9 is started at a timing when the heating device 20 is turned on through the operation of the heating switch 31 by the passenger of the vehicle 1, and the heating control process proceeds to a processing of step S51. Incidentally, this heating control process is repeatedly performed while the heating device 20 is on. Besides, the processing contents of steps S51 and S52 shown in FIG. 9 are identical to the processing contents of steps S31 and S32 shown in FIG. 7, so the description thereof will be omitted hereinafter and the description of a processing of step S53 will be given first.

In the processing of step S53, the ECU 38 acquires information on a speed limit, an angle of inclination and the like on a route (a running route) to be followed by the vehicle 1 from the navigation device 37, and predicts a transition of the load of the engine 2 on the running route based on the acquired information. In concrete terms, the ECU 38 predicts an average load of the engine 2 from the speed limit. Besides, the ECU 38 determines from map information whether the vehicle runs in an urban area, in a suburban area or on a freeway, and predicts a load of the engine 2 from an approximate vehicle speed. Besides, the ECU 38 predicts a continuity of a required load from an angle of inclination and an altitude (e.g., predicts that the engine operates at low load (or an accelerator is off) when the required load continues to fall and predicts that the engine operates at high load when the required load continues to rise). Besides, the ECU 38 predicts a required time and an average vehicle speed from information on traffic congestion and information on accidents and traffic regulations, and predicts a load from the required time and the average vehicle speed. Incidentally, the prediction of the load through the use of the information acquired from the navigation device 37 is an example. The ECU 38 may acquire route information from a traffic information transmission center or a running vehicle (through inter-vehicle communication) and accurate road environment information from an application in a terminal having positional information, such as a smartphone or the like, and reflect information on a meticulous running plan created based on the acquired information. Thus, the processing of step S53 is completed, and the heating control process proceeds to a processing of step S54.

In the processing of step S54, the ECU 38 calculates an amount of exhaust energy of the engine 2 on the running route, through the use of a prediction result of the transition of the load of the engine 2 on the running route in the processing of step S53 and a map indicating how the load of the engine 2 is related to the amount of exhaust energy of the engine 2. Thus, the processing of step S54 is completed, and the heating control process proceeds to a processing of step S55.

In the processing of step S55, the ECU 38 detects the temperature thw of engine coolant through the use of an electric signal that is output by the engine coolant temperature sensor 36, and determines whether or not the detected temperature thw of engine coolant is lower than a predetermined temperature. If the temperature thw of engine coolant is lower than the predetermined temperature as a result of the determination (Yes in step S55), the ECU 38 causes the heating control process to proceed to a processing of step S57. On the other hand, if the temperature thw of engine coolant is equal to or higher than the predetermined temperature (No in step S55), the ECU 38 causes the heating control process to proceed to a processing of step S56.

In the processing of step S56, the ECU 38 determines that engine coolant is in a warm water state, and performs engine coolant (warm water) heating operation such that the vehicle interior air-conditioning level detected in the processing of step S52 becomes equal to the required heating level detected in the processing of step S51. That is, the ECU 38 stops the operation of the heat pump 21, and heats the vehicle interior only through the use of engine coolant. Thus, the processing of step S56 is completed, and the heating control process returns to the processing of step S51.

In the processing of step S57, the ECU 38 determines whether or not the low-load state continues, by determining whether or not the amount of exhaust energy of the engine 2 on the running route, which has been calculated in step S54, has remained smaller than a predetermined value (e.g., 15 (kW)) for a predetermined time or over a predetermined distance. If the low-load state continues as a result of the determination (Yes in step S57), the ECU 38 causes the heating control process to proceed to a processing of step S59. On the other hand, if the low-load state does not continue (No in step S57), the ECU 38 causes the heating control process to proceed to a processing of step S58.

In the processing of step S58, the ECU 38 controls the operating point of the engine 2 to a target operating point that is defined as the same operating point of the engine 2 as at the time of normal operation when heating operation is not performed. Thus, the processing of step S58 is completed, and the heating control process proceeds to a processing of step S64.

In the processing of step S59, the ECU 38 detects a vehicle speed based on an electric signal that is output by the vehicle speed sensor 33, and determines, based on the detected vehicle speed, whether or not the vehicle 1 is stopped. If the vehicle 1 is stopped as a result of the determination (Yes in step S59), the ECU 38 causes the heating control process to proceed to a processing of step S60. On the other hand, if the vehicle 1 is running (No in step S59), the ECU 38 causes the heating control process to proceed to a processing of step S61.

In the processing of step S60, the ECU 38 charges the battery 10 by driving the generator 9 by the output of the engine, and controls the operating point of the engine 2 such that the load of the engine 2 becomes higher than at the operating point of the engine 2 at the time of normal operation when heating operation is not performed. Thus, the processing of step S60 is completed, and the heating control process proceeds to the processing of step S64.

In the processing of step S61, first of all, the ECU 38 detects a vehicle speed based on an electric signal that is output by the vehicle speed sensor 33, and detects an angle of inclination of the vehicle 1 in the longitudinal direction based on an electric signal that is output by the inclination sensor 34. Subsequently, the ECU 38 reads out a driving force of the vehicle 1 corresponding to the detected vehicle speed and the detected angle of inclination, as a driving force required by the driver, from a map indicating how the vehicle speed and the angle of inclination are related to the driving force of the vehicle 1. Then, the ECU 38 determines whether or not the driving force required by the driver is smaller than the predetermined value B. If the driving force required by the driver is smaller than the predetermined value B as a result of the determination (Yes in step S61), the ECU 38 causes the heating control process to proceed to a processing of step S62. On the other hand, if the driving force required by the driver is equal to or larger than the predetermined value B (No in step S61), the ECU 38 causes the heating control process to proceed to a processing of step S63.

In the processing of step S62, the ECU 38 controls the operating point of the engine 2 such that the load of the engine 2 increases while maintaining the rotational speed of the engine 2 at the operating point of the engine 2 at the time of normal operation when heating operation is not performed. Thus, the processing of step S62 is completed, and the heating control process proceeds to the processing of step S64.

In the processing of step S63, the ECU 38 controls the operating point of the engine 2 to a target operating point that is defined as an operating point of the engine 2 at which the load and rotational speed of the engine 2 are higher than at the time of normal operation when heating operation is not performed. Thus, the processing of step S63 is not completed, and the heating control process proceeds to the processing of step S64.

In the processing of step S64, the ECU 38 performs heat pump independent operation or heat pump & engine coolant cooperative operation such that the vehicle interior air-conditioning level detected in the processing of step S52 becomes equal to the required heating level detected in the processing of step S51. In concrete terms, the ECU 38 performs heat pump independent operation when the temperature of engine coolant is lower than the first threshold (see FIGS. 3B and 3C), and performs heat pump & engine coolant cooperative operation when the temperature of engine coolant is equal to or higher than the first threshold. Thus, the processing of step S64 is completed, and the heating control process returns to the processing of step S51.

As is apparent from the foregoing description, in the heating control process according to the fourth embodiment of the disclosure, the ECU 38 predicts the transition of the load of the engine 2 on the running route of the vehicle 1, and controls the operating point of the engine 2 in accordance with the predicted transition of the load. According to this configuration, an effect of making it possible to restrain a deterioration in fuel consumption or electric power consumption of the vehicle 1 from being caused due to the surplus generation of exhaust heat of the engine 2 at the time when the vehicle 1 runs along the running route can be achieved, in addition to the effects that are obtained by the heating control processes according to the above-mentioned first to third embodiments of the disclosure.

Although the embodiments to which the disclosure made by the inventors is applied have been described above, the disclosure is not limited by the description and drawings that constitute part of the disclosure of the embodiments of the disclosure. That is, other embodiments, working examples, operational technologies and the like devised by those skilled in the art or the like based on the present embodiments of the disclosure are all encompassed in the scope of the disclosure.

What is claimed is:

1. A control apparatus for a vehicle, the vehicle including a heating device that is configured to heat an interior of the vehicle through use of at least one of exhaust heat of an engine or an electric power of a battery, and running only through use of the electric power of the battery and through use of an output of the engine and the electric power of the battery, the control apparatus comprising an electronic control unit that is configured to:
when a heating operation is executed, control an operating point of the engine to a target operating point that is defined as a same operating point of the engine as at a time of normal operation when the heating operation is not performed, when the engine operates in a high-load region; and
when the heating operation is executed, control the operating point of the engine to a target operating point that is defined as an operating point of the engine at which the output of the engine is larger than at the time of normal operation, when the engine operates in a low-load region or an intermediate-load region.

2. The control apparatus for the vehicle according to claim 1, wherein the electronic control unit is configured to increase a load of the engine while holding a rotational speed of the engine constant, when the engine operates in the low-load region.

3. The control apparatus for the vehicle according to claim 1, wherein the electronic control unit is configured to:
when a charge amount of the battery becomes smaller than a predetermined value while the vehicle is stopped, heat the vehicle interior through use of exhaust heat of the engine by driving the engine; and
when the charge amount of the battery becomes smaller than the predetermined value while the vehicle is stopped, control the operating point of the engine to a target operating point that is defined as an operating point of the engine at which the load of the engine is higher than at the time of normal operation.

4. The control apparatus for the vehicle according to claim 1, wherein the electronic control unit is configured to:
predict a load of the engine on a running route of the vehicle; and
control the operating point of the engine in accordance with the predicted load.

5. A control method for a vehicle, the vehicle including a heating device that is configured to heat an interior of the vehicle through use of at least one of exhaust heat of an engine and an electric power of a battery, and running only through use of the electric power of the battery and through use of an output of the engine and the electric power of the battery, the control method comprising:
when a heating operation is executed, controlling an operating point of the engine to a target operating point that is defined as a same operating point of the engine as at a time of normal operation when the heating operation is not performed, when the engine operates in a high-load region; and
when the heating operation is executed, controlling the operating point of the engine to a target operating point that is defined as an operating point of the engine at which the output of the engine is larger than at the time of normal operation, when the engine operates in a low-load region or an intermediate-load region.
